(19) United States
(12) Patent Application Publication
(10) Pub. No.: US 2014/0127837 A1
(43) Pub. Date: May 8, 2014

(54) THIN FILM DEPOSITION APPARATUS AND METHOD OF DEPOSITING THIN FILM USING THE SAME

(71) Applicant: Jeong-Won HAN, Yongin-City (KR)

(72) Inventor: Jeong-Won HAN, Yongin-City (KR)

(21) Appl. No.: 13/789,845

(22) Filed: Mar. 8, 2013

(30) Foreign Application Priority Data
Nov. 5, 2012 (KR) 10-2012-0124473

(51) Int. Cl. H01L 21/66

(52) U.S. Cl. CPC H01L 22/12
USPC 438/14; 118/712

(57) ABSTRACT

A thin film deposition apparatus and a method of depositing a thin film using the thin film deposition apparatus, the thin film deposition apparatus including a chamber having a substrate and a mask mounted therein; a deposition source, the deposition source supplying a deposition gas to the substrate; and a mask measuring unit, the mask measuring unit measuring a status of the mask within the chamber.

### CROSS-REFERENCE TO RELATED PATENT APPLICATION

This application claims the benefit of Korean Patent Application No. 10-2012-0124473, filed on Nov. 5, 2012, in the Korean Intellectual Property Office, the disclosure of which is incorporated herein in its entirety by reference.

### BACKGROUND

1. Field

The embodiments relate to a thin film deposition apparatus and a method of depositing a thin film using the same.

2. Description of the Related Art

In thin film formation processes, e.g., formation of a thin film for an organic light-emitting diode (OLED) display, deposition techniques may include generating a vapor of a deposition source and depositing the same on a surface of a substrate. For example, a deposition process may include placing a mask on a substrate and allowing a vapor from a deposition source to pass through an aperture of the mask, and forming a thin film having a desired pattern on the substrate.

### SUMMARY

The embodiments provide a thin film deposition apparatus having an improved structure to directly and quickly detect the occurrence of a defect on a mask and a method of depositing a thin film using the same apparatus.

According to an embodiment, there is provided a thin film deposition apparatus including: a chamber having a substrate and a mask mounted therein; a deposition source for supplying a deposition gas to the substrate; and a mask measuring unit for measuring the status of the mask within the chamber.

The mask measuring unit may include a single measuring device that measures shape accuracy, aperture size, aperture uniformity, contamination level, and positioning accuracy of the mask.

The mask measuring unit may include a plurality of measuring devices, each of which is assigned different ones of shape accuracy, aperture size, aperture uniformity, contamination level, and positioning accuracy for measurement.

The mask may be split into a number of regions corresponding to the plurality of measuring devices. In this case, each of the plurality of measuring devices may be assigned one of the regions and measure shape accuracy, aperture size, aperture uniformity, contamination level, and positioning accuracy for the assigned region of the mask.

According to another aspect of the present invention, there is provided a method of depositing a thin film, which includes mounting a substrate and a mask within a chamber including a deposition source and a mask measuring unit; measuring the status of the mask by using the mask measuring unit; and replacing the mask as necessary according to the result of measurement.

The mask measuring unit may include a single measuring device which measures shape accuracy, aperture size, aperture uniformity, contamination level, and positioning accuracy of the mask.

The mask measuring unit may include a plurality of measuring devices, each of which measures different ones of shape accuracy, aperture size, aperture uniformity, contamination level, and positioning accuracy assigned thereto.

The mask may be split into a number of regions corresponding to the plurality of measuring devices. In this case, each of the plurality of measuring devices may be assigned one of the regions and measure shape accuracy, aperture size, aperture uniformity, contamination level, and positioning accuracy for the assigned region of the mask.

The thin film deposition apparatus and the thin film deposition method using the same according to the embodiments of the present invention allow early and direct detection of a defect on a mask and therefore prompt replacement of the defective mask. Thus, the occurrence of subsequent defects may be reduced, and the production efficiency may be significantly improved.

### BRIEF DESCRIPTION OF THE DRAWINGS

Features will become apparent to those of skill in the art by describing in detail exemplary embodiments with reference to the attached drawings in which:

FIGS. 1A and 1B illustrate constructions of a thin film deposition apparatus according to an embodiment;

FIGS. 2A and 2B illustrate constructions of a thin film deposition apparatus according to another embodiment; and

FIGS. 3A and 3B illustrate constructions of a thin film deposition apparatus according to another embodiment.

### DETAILED DESCRIPTION

Hereinafter, embodiments will be described in detail with reference to the accompanying drawings.

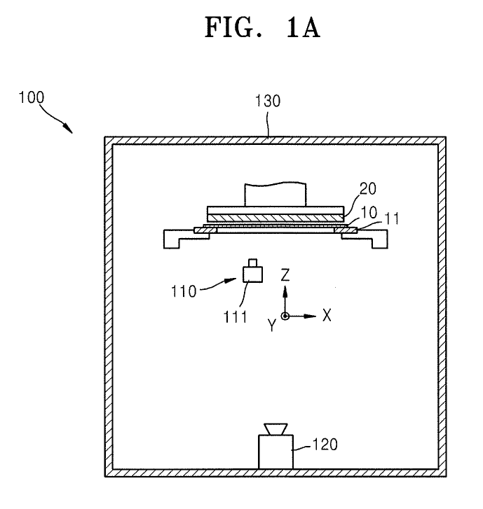

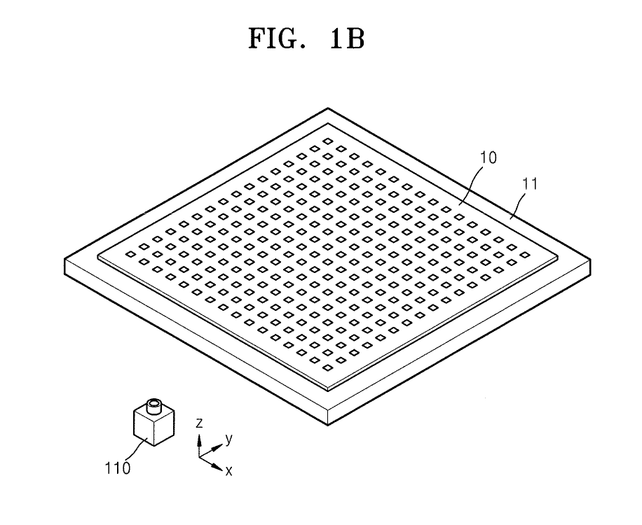

First, a thin film deposition apparatus 100 according to an embodiment will now be described with reference to FIGS. 1A and 1B.

Referring to FIGS. 1A and 1B, the thin film deposition apparatus 100 according to an embodiment may include a chamber 130 having a substrate 20 (that is a deposition target) and a mask 10 (for forming a desired pattern) fixedly attached on the substrate 20, a deposition source 120 (for spraying a deposition gas toward the mask 10 and the substrate 20), and a mask measuring unit 110 (for directly inspecting a status of the mask 10 within the chamber 130). The thin film deposition apparatus 100 may further include a mask frame 11.

Thus, when the deposition source 120 discharges a deposition gas within the chamber 130, the deposition gas passes through an aperture in the mask 10 and is deposited on the substrate 20 to thereby form a thin film having a predetermined pattern.

As described above, the mask measuring unit 110 may be installed in the chamber 130 to directly measure the presence of a defect on the mask 10 within the chamber 130. Thus, this direct measurement may facilitate quicker and more accurate determination and measures to be made than an indirect measurement technique whereby the status of the mask 110 is inferred from the resulting material.

The mask measuring unit 110 may include a single measuring device 111 that measures, e.g., shape accuracy, aperture size, aperture uniformity, contamination level, and positioning accuracy of the mask 10. For example, the contamination level may be determined by irradiating the mask 10 with infrared light and measuring an amount of reflected light. When the mask 10 is severely contaminated, much of the infrared light may be absorbed, so the amount of reflected light may be reduced. Furthermore, the presence of a defect may be determined by comparing the shape accuracy, aperture size, aperture uniformity, and positioning accuracy with corresponding references previously input after taking a picture of the mask 10 with a camera.

A common three-axis actuator permits the measuring device 111 to move along X, Y, and Z axes. The measuring device 111 may move across the mask 10 within the chamber 130 to measure the shape accuracy, aperture size, aperture uniformity, contamination level, and positioning accuracy of the mask 10. A method of depositing a thin film using the thin film deposition apparatus 100 will now be described.

First, after the mask 10 and the substrate 20 are mounted in the chamber 130 for a deposition process, the measuring device 111 may check the status of the mask 10 before the deposition source 120 operates. The measuring device 111 may then move across the mask 10 to measure shape accuracy, aperture size, aperture uniformity, contamination level, and positioning accuracy of the mask 10. Upon detecting a failure in the status of the mask 10, the defective mask 10 may be immediately replaced with another mask 10, and the other mask 10 is inspected for defects. When no failure is detected in the status of the mask 10, the measuring device 111 may move outside the mask 10, and then the deposition source 120 may start deposition of a thin film onto the substrate 20.

The above-described inspection of the mask 10 may be performed before the beginning of or after completion of the deposition.

Inspecting the mask 10 within the chamber 130 by using the measuring device 111 may facilitate direct and fast detection of a failure in the mask 10 and therefore prompt replacement of the defective mask 10. Thus, use of the thin-film deposition apparatus 100 may help reduce the product failure rate and may help improve the production efficiency.

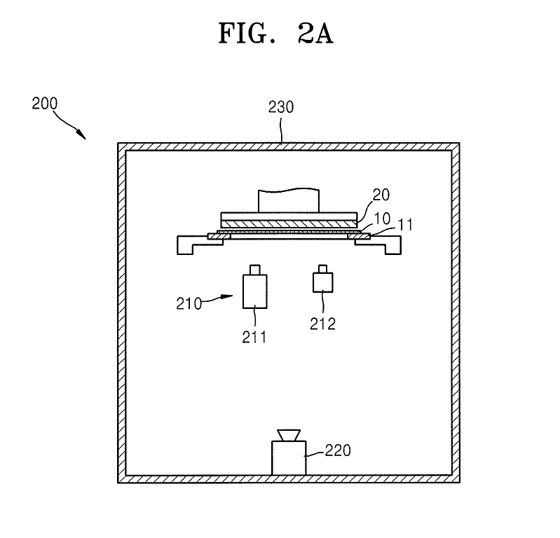

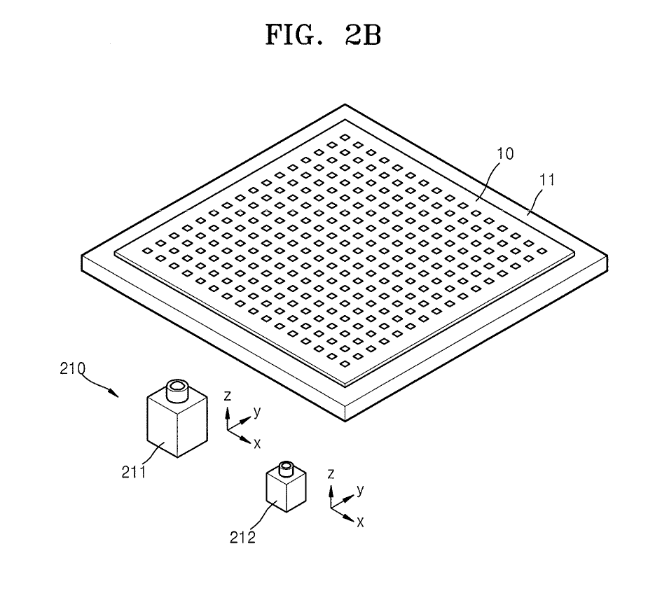

FIGS. 2A and 2B illustrate constructions of a thin film deposition apparatus 200 according to another embodiment.

Referring to FIGS. 2A and 2B, the thin film deposition apparatus 200 according to the present embodiment may include a chamber 230 having a substrate 20 (that is a deposition target) and a mask 10 (for forming a desired pattern) fixedly attached on the substrate 20, a deposition source 220 (for spraying a deposition gas toward the mask 10 and the substrate 20), and a mask measuring unit 210 (for directly inspecting the status of the mask 10 within the chamber 230).

Thus, when the deposition source 220 discharges a deposition gas within the chamber 230, the deposition gas passes through an aperture in the mask 10 and may be deposited on the substrate 20 to thereby form a thin film having a predetermined pattern.

The mask measuring unit 210 may include a plurality of measuring devices, e.g., first and second measuring devices 211 and 212. The first measuring device 211 may measure a contamination level of the mask 10 while the second measuring device 212 may measure shape accuracy, aperture size, aperture uniformity, and positioning accuracy. For example, instead of using the single measuring device 111 to measure all factors as described in the previous embodiment, the first and second measuring devices 211 and 212 may be assigned some of the factors for measurement, wherein the assigned factors are different from each other. For example, the first measuring device 211 may determine the contamination level by irradiating the mask 10 with infrared light and measuring the amount of reflected light. When the mask 10 is severely contaminated, the amount of reflected light may be reduced since much of the infrared light may be absorbed. In addition, the second measuring device 212 may measure the shape accuracy, aperture size, aperture uniformity, and positioning accuracy by comparing them with corresponding references previously input after taking a picture of the mask 10 with a camera.

A common three-axis actuator may allow the first and second measuring devices 211 and 212 to move along X, Y, and Z axes. The first and second measuring devices 211 and 212 move across the mask 10 within the chamber 230 to measure the contamination level, and the shape accuracy, aperture size, aperture uniformity and positioning accuracy of the mask 10, respectively.

A method of depositing a thin film using the thin film deposition apparatus 200 will now be described.

First, after the mask 10 and the substrate 20 are mounted in the chamber 230 for a deposition process, the first and second measuring devices 211 and 212 may sequentially operate to check the status of the mask 10 before the deposition source 220 operates. The first measuring device 211 may move across the mask 10 to measure a contamination level, and subsequently, the second measuring device 212 may move across the mask 10 to measure shape accuracy, aperture size, aperture uniformity, and positioning accuracy of the mask 10. Upon detecting a failure in the status of the mask 10, the defective mask 10 may be immediately replaced with another mask 10, and then the other mask 10 may be inspected for defects. When no failure is detected in the status of the mask 10, the first and second measuring devices 211 and 212 may move outside the mask 10, and then the deposition source 220 may operate so as to start deposition of a thin film onto the substrate 20.

The above-described inspection of the mask 10 may be performed before the beginning of or after completion of the deposition.

Inspecting the mask 10 in the chamber 230 by using the mask measuring unit 210 may facilitate direct and fast detection of a failure in the mask 10 and therefore prompt replacement of the defective mask 10. Thus, use of the thin-film deposition apparatus 200 may help reduce the product failure rate and may help improve the production efficiency.

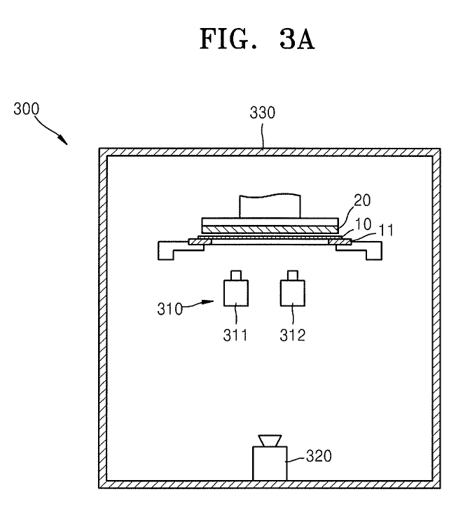

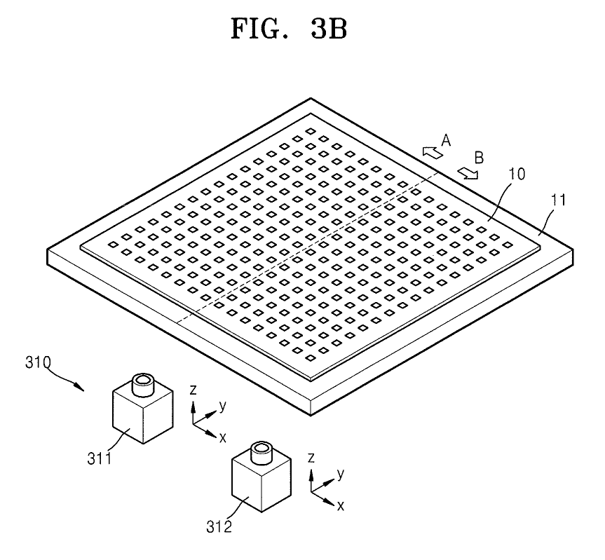

FIGS. 3A and 3B illustrate constructions of a thin film deposition apparatus 300 according to another embodiment.

Referring to FIGS. 3A and 3B, the thin film deposition apparatus 300 according to the present embodiment may include a chamber 330 having a substrate 20 (that is a deposition target) and a mask 10 (for forming a desired pattern) fixedly attached on the substrate 20, a deposition source 320 (for spraying a deposition gas toward the mask 10 and the substrate 20), and a mask measuring unit 310 (for inspecting the status of the mask 10 within the chamber 330).

Thus, when the deposition source 320 discharges a deposition gas within the chamber 330, the deposition gas passes through an aperture in the mask 10 and may be deposited on the substrate 20 to thereby form a thin film having a predetermined pattern.

The mask measuring unit 310 may include a plurality of measuring devices, e.g., first and second measuring devices 311 and 312. Each of the first and second measuring devices 311 and 312 may measure shape accuracy, aperture size, aperture uniformity, contamination level, and positioning accuracy. In this case, the mask 10 may be partitioned into, e.g., two, regions for measurement. The first or second measuring device 311 and 312 may be assigned one of the two regions. Referring to FIG. 3B, the first measuring device 311 may measure the above-described factors for region A while the second measuring device 312 may measure the same for region B.

Like in the previous embodiments, the contamination level may be determined by irradiating the mask 10 with infrared light and measuring the amount of reflected light. The shape accuracy, aperture size, aperture uniformity, and positioning accuracy may be measured by comparing them with corresponding references previously input after taking a picture of the mask 10 with a camera.

A common three-axis actuator permits the first and second measuring devices 311 and 312 to move along X, Y, and Z axes. The first and second measuring devices 311 and 312 may move across the mask 10 within the chamber 330 to measure the contamination level, the shape accuracy, aperture size, aperture uniformity and positioning accuracy of the mask 10, respectively.

A method of depositing a thin film using the thin film deposition apparatus 300 will now be described.

First, after the mask 10 and the substrate 20 are mounted in the chamber 330 for a deposition process, the first and second measuring devices 311 and 312 may check the status of the mask 10 before the deposition source 320 operates. The first and the second measuring devices 311 and 312 may move across the mask 10 to measure the contamination level, shape accuracy, aperture size, aperture uniformity, and positioning accuracy for region A and region B of the mask 10, respectively. Upon detecting a failure in the status of the mask 10, the defective mask 10 may be immediately replaced with another mask 10, and then the other mask 10 may be inspected for defects. When no failure is detected in the status of the mask 10, the first and second measuring devices 311 and 312 may move outside the mask 10, and then the deposition source 320 operates so as to start deposition of a thin film onto the substrate 20.

The above-described inspection of the mask 10 may be performed before the beginning of or after completion of the deposition.

Inspecting the mask 10 in the chamber 330 by using the mask measuring unit 310 may facilitate direct and fast detection of a failure in the mask 10 and therefore prompt replacement of the defective mask 10. Thus, use of the thin-film deposition apparatus 300 may reduce the product failure rate and improve the production efficiency.

By way of summation and review, when defects occur due to an uneven aperture of a mask and clogging of the aperture with contaminants during a deposition process, it may only be possible to detect the occurrence of defects from the resulting material. For example, it may be difficult to directly identify defects in a mask during a deposition process. Thus, the presence of the defects may be inferred from the status of a thin film to be formed on a substrate.

Accordingly, measures cannot be taken to compensate for defects in a mask in a timely manner. Furthermore, once a defect occurs in a mask, the number of defects will continue to increase until the defect is found. This may significantly degrade the production efficiency.

The thin film deposition apparatus according to an embodiment is capable of forming a thin film on a surface of an object by generating a vapor of a deposition source, and more particularly, to a thin film deposition apparatus for forming a deposition pattern by using a mask and a method of depositing a thin film using the same apparatus.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A thin film deposition apparatus, comprising:
a chamber having a substrate and a mask mounted therein;
a deposition source, the deposition source supplying a deposition gas to the substrate; and
a mask measuring unit, the mask measuring unit measuring a status of the mask within the chamber.

2. The apparatus of claim 1, wherein the mask measuring unit includes a single measuring device.

3. The apparatus of claim 2, wherein the single measuring device measures shape accuracy, aperture size, aperture uniformity, contamination level, and positioning accuracy of the mask.

4. The apparatus of claim 1, wherein the mask measuring unit includes a plurality of measuring devices.

5. The apparatus of claim 4, wherein each of the plurality of measuring devices respectively measure at least one of shape accuracy, aperture size, aperture uniformity, contamination level, or positioning accuracy.

6. The apparatus of claim 4, wherein:
the mask is split into a number of regions corresponding to a number of the plurality of measuring devices, and
each of the plurality of measuring devices measures shape accuracy, aperture size, aperture uniformity, contamination level, and positioning accuracy in one of the regions of the mask.

7. A method of depositing a thin film, the method comprising:
mounting a substrate and a mask within a chamber that includes a deposition source and a mask measuring unit;
measuring a status of the mask with the mask measuring unit; and
replacing the mask as necessary according to a result of measurement.

8. The method of claim 7, wherein the mask measuring unit includes a single measuring device.

9. The method of claim 8, wherein measuring the status of the mask with the mask measuring unit includes measuring shape accuracy, aperture size, aperture uniformity, contamination level, and positioning accuracy of the mask with the single measuring device.

10. The method of claim 7, wherein the mask measuring unit includes a plurality of measuring devices.

11. The method of claim 10, wherein measuring the status of the mask with the mask measuring unit includes each of the plurality of measuring devices respectively measuring at least one of shape accuracy, aperture size, aperture uniformity, contamination level, and positioning accuracy of the mask.

12. The method of claim 10, wherein:
the mask is split into a number of regions corresponding to a number of the plurality of measuring devices, and
measuring the status of the mask with the mask measuring unit includes each of the plurality of measuring devices measuring shape accuracy, aperture size, aperture uniformity, contamination level, and positioning accuracy in one of the region of the mask, respectively.
